(19) United States
(12) Patent Application Publication
(10) Pub. No.: US 2025/0393479 A1
(43) Pub. Date: Dec. 25, 2025

(54) MRAM WITH DUAL SPACER AND TOP VIA

(71) Applicant: International Business Machines Corporation, Armonk, NY (US)

(72) Inventors: Ashim Dutta, Clifton Park, NY (US); Shravana Kumar Katakam, Lehi, UT (US); Chih-Chao Yang, Glenmont, NY (US)

(21) Appl. No.: 18/748,544

(22) Filed: Jun. 20, 2024

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A magnetoresistive-random-access-memory (MRAM) cell includes a bottom electrode, a first layer is located on top of the bottom electrode, a magnetic-tunnel-junction (MTJ) is located on top of the first layer, a top electrode is located on top of the MTJ. A first spacer is located around the bottom electrode, the first layer, the MTJ, and a portion of the top electrode. A second spacer is located around the first spacer. The second spacer is located around the side surfaces and the top surface of the top electrode. A contact is connected to the top electrode, where the contact extends through the second spacer to contact the top electrode.

### BACKGROUND

The present invention generally relates to the field of microelectronic devices, and more particularly to controlling an over etch to prevent defects from developing.

Nanosheet is the lead device architecture in continuing CMOS scaling are fabricated on the same chip/wafer as MRAM. The height difference between different devices on the same chip/wafer can have different process window margins for opens/shorts. Meaning that the normal process for one part of the device can lead to an open/short being formed in another part of the device.

### BRIEF SUMMARY

Additional aspects and/or advantages will be set forth in part in the description which follows and, in part, will be apparent from the description, or may be learned by practice of the invention.

A magnetoresistive-random-access-memory (MRAM) cell includes a bottom electrode, a first layer is located on top of the bottom electrode, a magnetic-tunnel-junction (MTJ) is located on top of the first layer, a top electrode is located on top of the MTJ. A first spacer is located around the bottom electrode, the first layer, the MTJ, and a portion of the top electrode. A second spacer is located around the first spacer. The second spacer is located around the side surfaces and the top surface of the top electrode. A contact is connected to the top electrode, where the contact extends through the second spacer to contact the top electrode.

A magnetoresistive-random-access-memory (MRAM) cell includes a bottom electrode, a first layer is located on top of the bottom electrode, a magnetic-tunnel-junction (MTJ) is located on top of the first layer, a top electrode is located on top of the MTJ. A first spacer is located around the bottom electrode, the first layer, the MTJ, and a portion of the top electrode. A second spacer is located around the first spacer. The second spacer is located around the side surfaces and the top surface of the top electrode. A contact is connected to the top electrode, where the contact extends through the second spacer to contact the top electrode. The contact wraps unevenly around the sides of the top electrode.

A microelectronic structure that includes a magnetoresistive-random-access-memory (MRAM) array that includes a plurality of MRAM cells. Each of the plurality of MRAM cells includes a bottom electrode, a first layer is located on top of the bottom electrode, a magnetic-tunnel-junction (MTJ) is located on top of the first layer, a top electrode is located on top of the MTJ. A first spacer is located around the bottom electrode, the first layer, the MTJ, and a portion of the top electrode. A second spacer is located around the first spacer. The second spacer is located around the side surfaces and the top surface of the top electrode. A plurality of contacts where each of the plurality of contacts is connected to one of the MRAM cells. Each of the plurality of contacts is connected to the top electrode of one of the plurality of MRAM cells. The contact wraps unevenly around the sides of the top electrode or the contact wraps evenly around the sides of the top electrode.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross-section of the logic region after the initial processing, in accordance with an embodiment of the present invention.

FIG. 2 illustrates a cross-section of the memory region after the initial processing, in accordance with an embodiment of the present invention.

FIG. 3 illustrates a cross-section of the logic region after removal of a plurality of layer and the formation of a first spacer, in accordance with an embodiment of the present invention.

FIG. 4 illustrates a cross-section of the memory region after etching of the layer to form the MRAM stack and the formation of the first spacer, in accordance with an embodiment of the present invention.

FIG. 5 illustrates a cross-section of the logic region after removal of the first spacer, in accordance with an embodiment of the present invention.

FIG. 6 illustrates a cross-section of the memory region after etching of the first spacer, in accordance with an embodiment of the present invention.

FIG. 7 illustrates a cross-section of the logic region after formation and etch back of a second spacer, in accordance with an embodiment of the present invention.

FIG. 8 illustrates a cross-section of the memory region after formation and etch back of a second spacer, in accordance with an embodiment of the present invention.

FIG. 9 illustrates a cross-section of the logic region after formation of an interlayer dielectric layer, in accordance with an embodiment of the present invention.

FIG. 10 illustrates a cross-section of the memory region after formation of an interlayer dielectric layer, in accordance with an embodiment of the present invention.

FIG. 11 illustrates a cross-section of the logic region after formation of a logic contact via and trench, in accordance with an embodiment of the present invention.

FIG. 12 illustrates a cross-section of the first memory region after formation of an extend contact via and trench, in accordance with an embodiment of the present invention.

FIG. 13 illustrates a cross-section of the second memory region after formation of an ideal aligned contact trench, in accordance with an embodiment of the present invention.

FIG. 14 illustrates a cross-section of the third memory region after formation of a miss-aligned contact trench, in accordance with an embodiment of the present invention.

FIG. 15 illustrates a cross-section of the logic region after formation of a logic contact, in accordance with an embodiment of the present invention.

FIG. 16 illustrates a cross-section of the first memory region after formation of an extended contact, in accordance with an embodiment of the present invention.

FIG. 17 illustrates a cross-section of the second memory region after formation of an ideal aligned contact, in accordance with an embodiment of the present invention.

FIG. 18 illustrates a cross-section of the third memory region after formation of a miss-aligned contact, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards utilizing a second spacer to control the over etching that can occur because of different thickness/depths/heights of different layers. For example, during the fabrication processing of a chip/wafer/device, a plurality of different connection vias are formed to make connections to different devices, such as, logic circuits, MRAM, passive device, interconnects, different levels, etc. The depth of the vias can vary between the different devices, locations, and/or within the devices themselves. The devices that have shorter vias (i.e., a lower depth) can be over etched caused by the etching of the deeper vias (i.e., a larger depth), where the over etching can cause defects to be formed. The defects can be for example, the exposure of different layers, the removal of spacers/insulators/dielectric layers, electric shorts, etc. The present invention utilizes a second spacer to control the over etching in desired locations. During the over etching at different locations, the second spacer is laterally etched instead of the over etching extending downwards along the device, thus the second spacer controls the direction of the over etch instead of allowing it to expose different layers of the device.

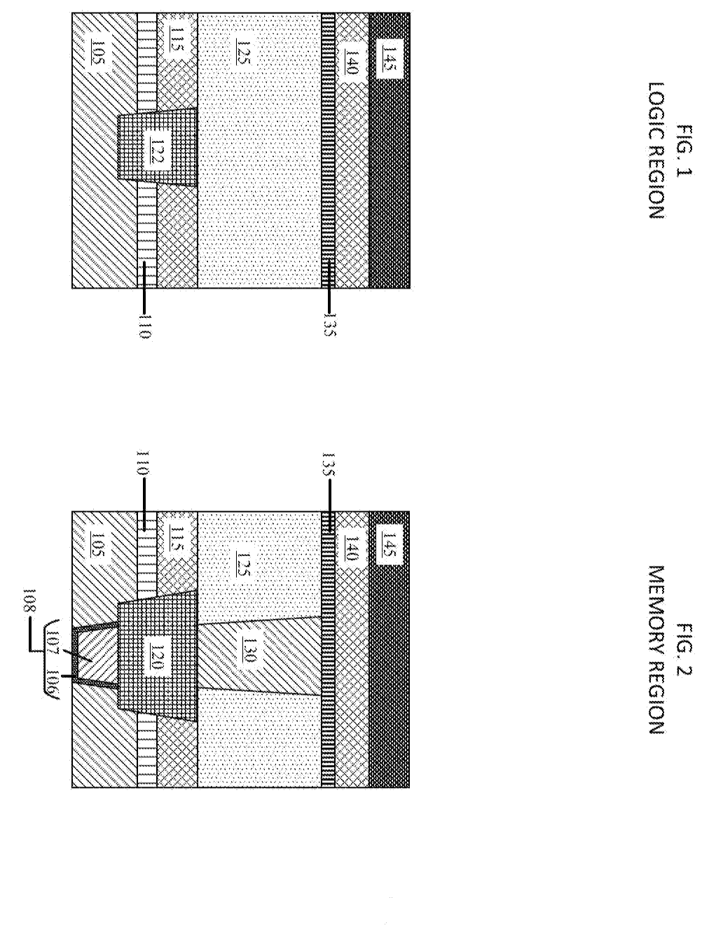

Referring now to FIG. 1, a structure is shown in the logic region during an intermediate step of a method of formation of the initial layers. FIG. 1 illustrates a portion of the logic circuit or logic region on the chip/wafer. The logic region includes a first layer 105, a cap layer 110, an interlayer dielectric layer 115, a logic connector 122, a second layer 125, a third layer 135, a magnetic tunnel junction (MTJ) layer 140, and conductive metal layer 145. The first layer 105 can be comprised of, for example, an oxide material, such as Tetraethyl Orthosilicate (TEOS). The cap layer 110 can be comprised of, for example, an oxide, a nitride, TEOS, SiN, SiCHN, or another suitable material. The logic connector 122 is comprised of a conductive metal that is connected to a logic circuit (not shown) on the chip/wafer. The second layer 125 can be comprised of, for example, SiN, SiCN(H), TEOS, other oxides, nitrides, or other suitable materials. The third layer 135 can be comprised of, for example, TaN, TiN, or other hardmask materials, or combinations thereof.

The magnetic tunnel junction (MTJ) layer 140 is comprised of a plurality of layers. The individual layers of the MTJ layer 140 are not shown, but the MTJ layer includes a reference layer, a tunnel barrier layer, and a free layer. The material for the reference layer can be selected from a group that includes CoFeB layers with Fe Co, Pt, or Ta. The tunnel barrier layer can be selected from a group that includes MgO or Al₂O₃. The free layer can be selected from a group that includes CoFeB multi-layers with Mo, Pt, or Ta. The conductive metal layer 145 can be selected from a group that includes Nb, NbN, W, WN, Ta, TaN, Ti, TiN, Ru, Cu, Co, W, Mo, Cr, V, Pd, Pt, Rh, Sc, Al, other high melting point metals, other suitable conductive metals, conductive alloys, or a combination thereof.

Referring now to FIG. 2, a structure is shown in the memory region during an intermediate step of a method of formation of the initial layers. FIG. 2 illustrates a portion of the memory circuit (MRAM circuit) or memory region on the chip/wafer. FIG. 2 illustrates similar layers as described above and will not be repeated for brevity. There are differences between the memory region and the logic region. The first difference is the connection 108 to the underlying device, where the connection 108 could include a first component 106 and a second component 107. The connection 108 is connected to a metal line/connector 120. The bottom electrode 130 is connected to the metal line/connector 120. The third layer 135 is located on the top surface of the bottom electrode 130. The bottom electrode 130 can be comprised of, for example, Nb, NbN, W, WN, Ta, TaN, Ti, TiN, Ru, Cu, Co, W, Mo, WN, Cr, V, Pd, Pt, Rh, Sc, Al, other high melting point metals, other suitable conductive metals, conductive alloys, or a combination thereof

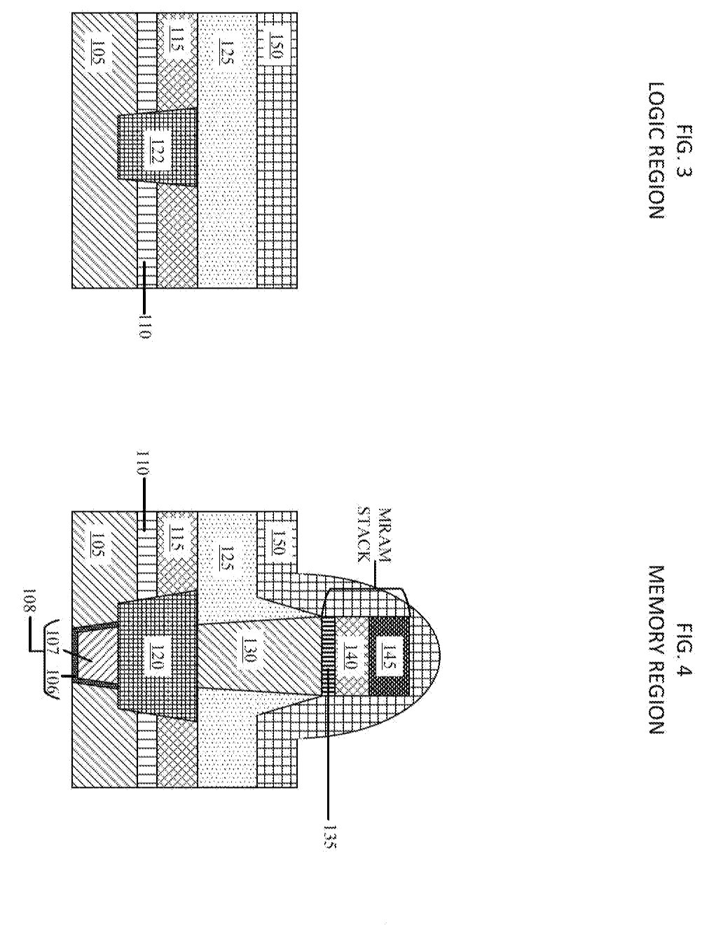

FIG. 3 illustrates the processing stage of the logic region after the removal of multiple layers and the formation of the first spacer 150. The third layer 135, magnetic tunnel junction (MTJ) layer 140, and conductive metal layer 145 are removed in the logic region. The second layer 125 is etch back/pull down to reduce the height of the second layer 125. A first spacer 150 is formed on top of the second layer 125. FIG. 4 illustrates the processing stage of the memory region after etching multiple layers to form one or more MRAM stacks and the formation of the first spacer 150. The third layer 135, magnetic tunnel junction (MTJ) layer 140, and conductive metal layer 145 are etched to form one or more MRAM stack located on top of each of the bottom electrodes 130. FIG. 4 only illustrates a single MRAM stack, but it is well within the skill level of one of ordinary skill in the art to realize that this is meant to only act as an illustrative example of the present invention, and that a plurality of MRAM stacks is formed in the memory region. The etching of the conductive metal layer 145 will form the top electrode located in the MRAM stack, thus conductive metal layer 145 hereinafter will be referred to as the top electrode 145. FIG. 4 only illustrates one MRAM stack, but it is obvious to one of ordinary skill in the art that the memory region includes a plurality of bottom electrodes 130 and a plurality of MRAM stacks (comprised of the third layer 135, magnetic tunnel junction (MTJ) layer 140, and top electrode 145), where each of the plurality of MRAM stacks is located on one of the plurality of bottom electrodes 130. The second layer 125 is etch/pulled down such that the second layer is located around the bottom electrode 130. The first spacer 150 is formed on top of the second layer 125 and encloses the MRAM stack (comprised of the third layer 135, magnetic tunnel junction (MTJ) layer 140, and top electrode 145). The first spacer 150 can be comprised of, for example, SiN, SiCN(H), SiC, or another suitable material. The second layer 125 is located between the bottom electrode 130 and the first spacer 150. The first spacer 150 is located on and adjacent to the plurality of sides of the MRAM stack, for example, the first spacer 150 is located along the sides of the third layer 135, the MTJ layer 140, and the top electrode 145. Furthermore, the first spacer 150 extends over and on top of the top electrode 145, such that, the first spacer 150 is in contact with a top surface of the first electrode 145.

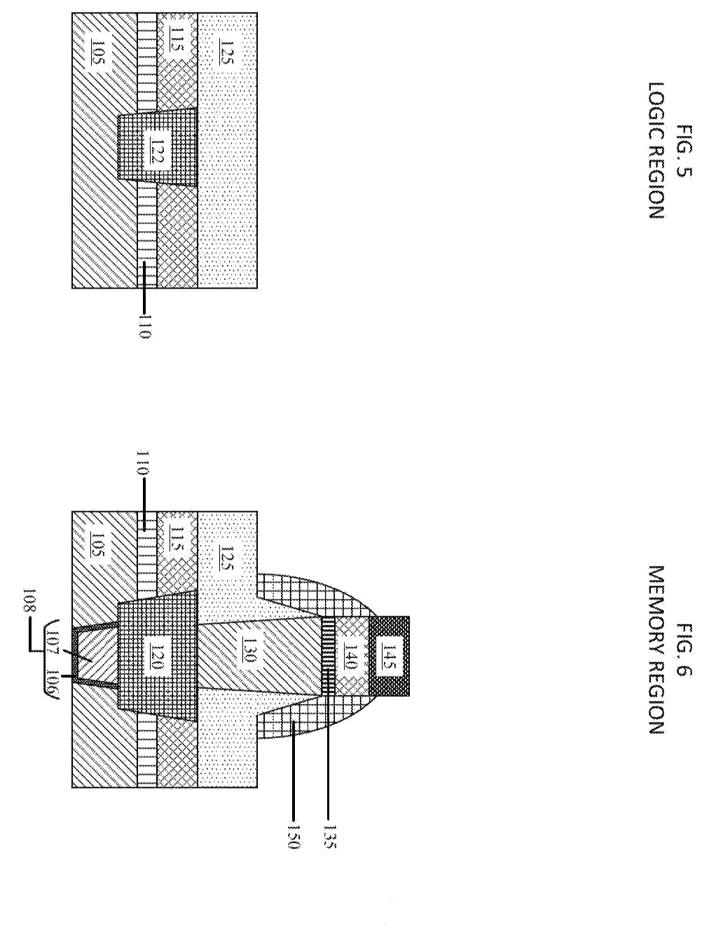

FIG. 5 illustrates the processing stage of the logic region after etching of the first spacer 150. The first spacer 150 is etched in the memory region and removed in the logic region such that the removal of the first spacer 150 in the logic region exposes the second layer 125. FIG. 6 illustrates the processing stage after etching of the first spacer 150. The first spacer 150 is etched/pulled down to expose a portion of the top electrode 145. The etching of the first spacer 150 further exposes portions of the second layer 125. The first spacer 150 is not etch/pulled down to expose the entire side wall of the top electrode 145. The first spacer 150 is still located around the sides of the third layer 135 and the MTJ layer 140. The first spacer 150 extends high enough to contact a bottom portion of the top electrode 145 to prevent the MTJ layer 140 from being exposed.

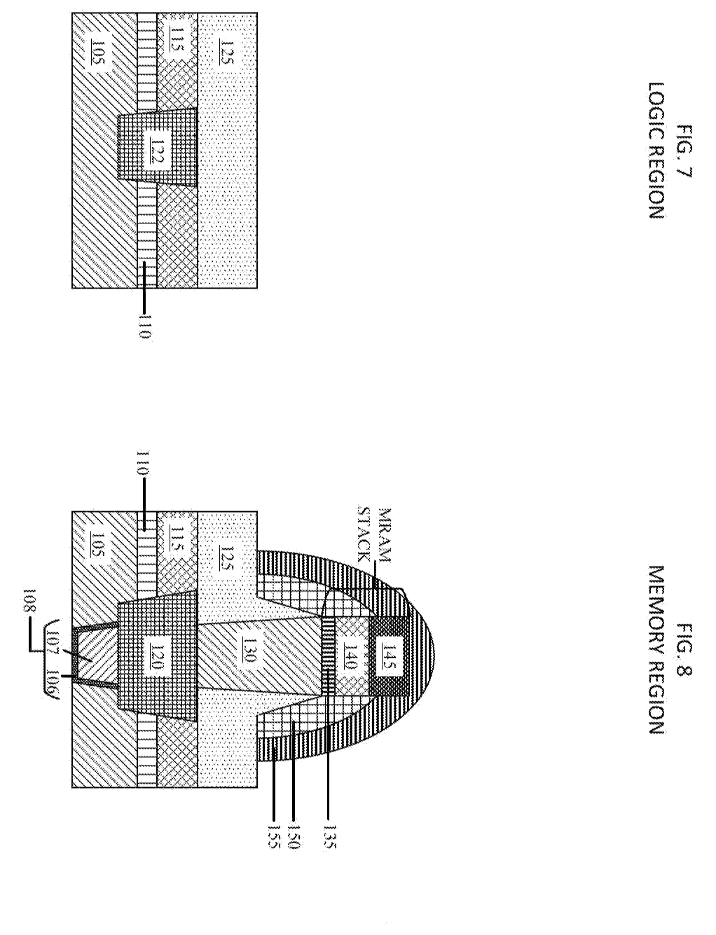

FIG. 7 illustrates the processing stage of the logic region after formation and etch back of a second spacer 155. The second spacer 155 is formed on top of the second layer 125 and etch back to remove the second spacer 155 from the logic region. FIG. 8 illustrates the processing stage of the memory region after formation and etch back of a second spacer 155. The second spacer 155 is formed on the exposed surfaces of the second layer 125, the first spacer 150, and the top electrode 145. The second spacer 155 is etched back to remove excess material. The second spacer 155 encloses the first spacer 150 and encloses the top electrode 145. The second spacer 155 extends from the second layer 125 to reach and cover the top surface of the top electrode 145. Therefore, the second spacer 150 encloses a portion of the bottom electrode 130 and the MRAM stack as illustrated in FIG. 8. The second spacer 155 can be comprised of, for example, SiOₓ, SiCO, or other suitable materials.

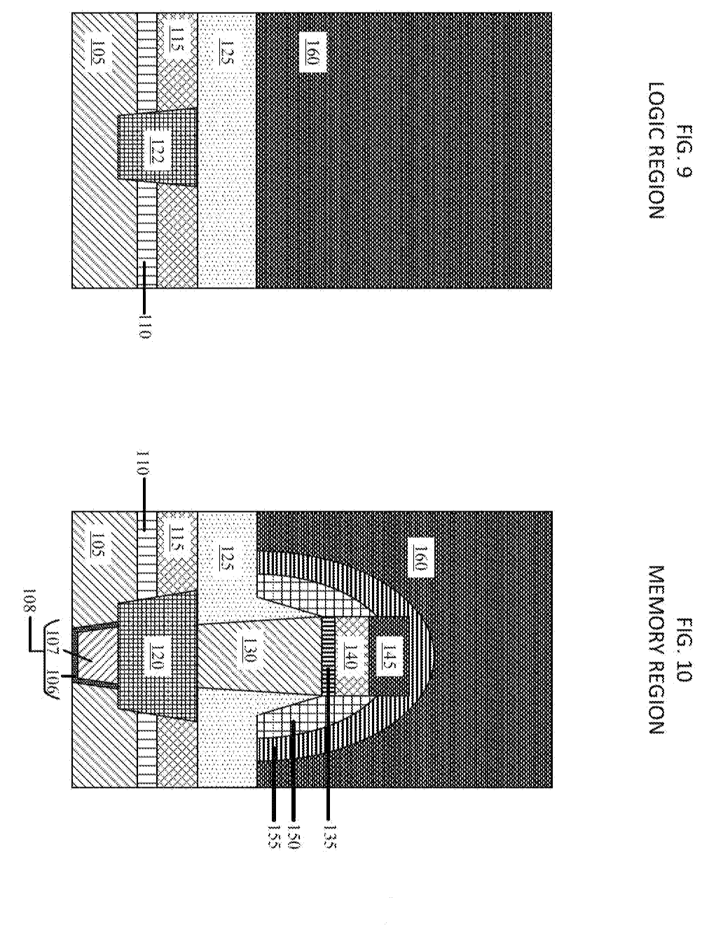

FIG. 9 illustrates the processing stage of the logic region after formation of an interlayer dielectric layer 160. An interlayer dielectric layer 160 is formed on top of the second layer 125. FIG. 10 illustrates the processing stage of the memory region after formation of an interlayer dielectric layer 160. The interlayer dielectric layer 160 is formed on top of the second layer 125 and on top of the second spacer 155. The interlayer dielectric layer 160 encloses/surrounds the second spacer 155.

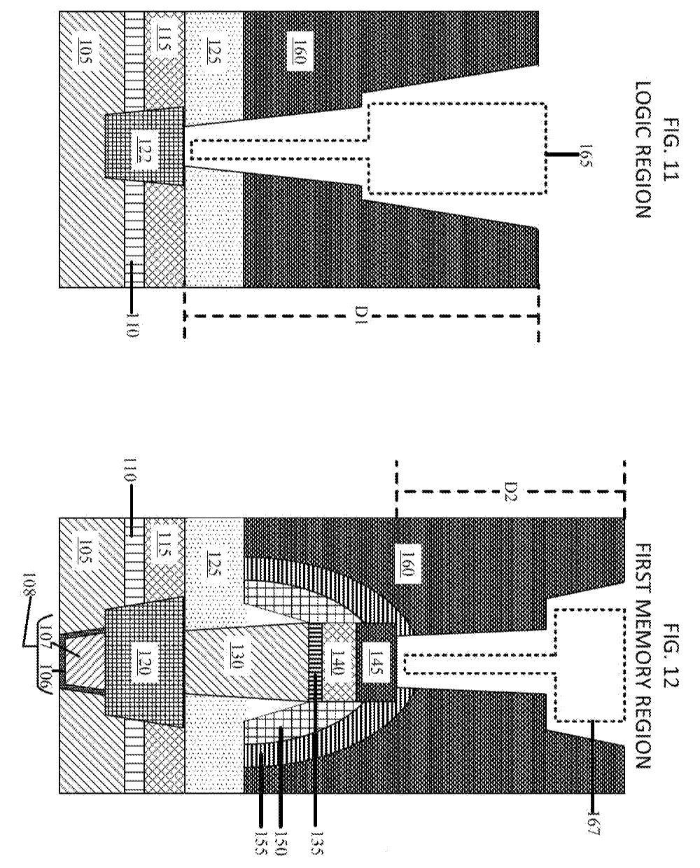

FIG. 11 illustrates the processing stage of the logic region after the formation of logic contact via trench 165. The logic contact via trench 165 is formed in the interlayer dielectric layer 160 and the second layer 125 to expose a top surface of the logic connector 122. The depth/height/dimension of the logic contact via trench 165 is represented by the reference number D1. The depth/height/dimension D1 can be greater than the depth/height/dimension needed to form the trenches in the memory region, which can lead to over etching in the memory region since the etching process is conducted at the same time. The over etching in the memory region can lead to different parts of the MRAM stack being exposed when they should not be, for example, the MTJ layer 140 could be exposed because of the over etching. If MTJ layer 140 is exposed by the over etching, then when the contacts are formed for the MRAM stack, the conductive metal of the contact can be in direct contact with the MTJ layer 140. This will lead to a short or a defect in the MRAM cell.

FIG. 12 illustrates the processing stage of the first memory region after the formation of the extended trench 167. The first memory region is an example of a memory region where the height/depth/dimension of the extended trench 167 is enough to lead to the over etching of MRAM stacks located in other memory regions. An extended trench 167 is formed in the interlayer dielectric layer 160 and the second spacer 155 to expose a top surface of the top electrode 145. The extended trench 167 has a depth/height/dimension D2 that is large enough to lead to the over etching of MRAM stacks located in other memory regions. The scenarios illustrated by FIGS. 11 and 12 are meant to only show different situations that can lead to over etching of MRAM stacks located in other memory regions. These scenarios, individually, or together can be found in the final structure of the chip/wafer. Additionally other scenarios could individually or in any combination that can lead to over etching of MRAM stacks located in other memory regions. The present invention is directed to controlling the over etching in the memory region to prevent the formation of defects in the MRAM cells.

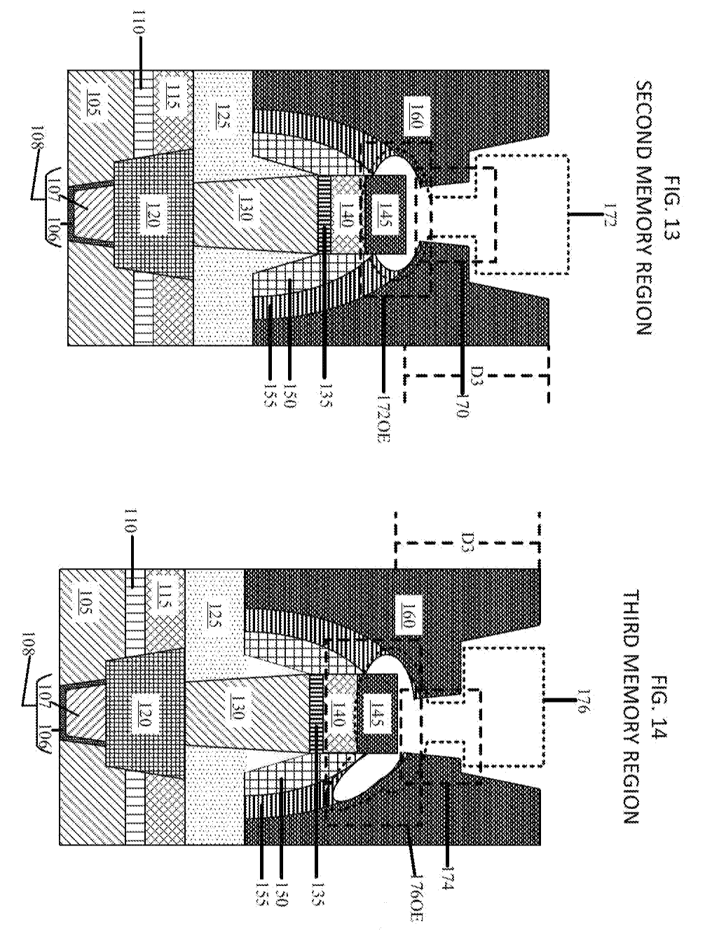

FIG. 13 illustrates the processing stage of the second memory region after the formation of the ideal aligned contact trench 172. FIG. 13 illustrates a second memory region where the depth/height/dimension D3 of the ideal aligned contact trench 172 is small enough that the deeper etching in other regions/areas will lead to over etching of the ideal aligned contact trench 172. A trench and a via are formed in the interlayer dielectric layer 160, where the trench and via (as emphasized by dashed box 170) are aligned over substantially the center of the top electrode 145 to form the ideal aligned contact trench 172. The ideal aligned contact trench 172 exposes the top surface of the top electrode 145. Since the depth/height/dimension D3 is such that ideal aligned contact trench 172 will be over etched because the longer etch time that is needed to etch other regions. The over etching will laterally etch the second spacer 155 instead of etching further downwards into the first spacer 150. The over etch portion, as emphasized by dashed box 172OE, illustrates how lateral cavities are formed in the second spacer 155 during the over etching of the ideal aligned contact trench 172. The over etched portion 172OE does not extend downwards into the first spacer 150, but instead extends laterally into the second spacer 155.

FIG. 14 illustrates the processing stage of the third memory region after the formation of the miss-aligned contact trench 176. FIG. 13 illustrates a second memory region where the depth/height/dimension D3 of the miss-aligned contact trench 176 is small enough that the deeper etching in other regions/areas will lead to over etching of the miss-aligned contact trench 176. The different types of scenarios illustrated by FIGS. 12, 13 and 14 can be in in a memory region in a chip separately, combined, or any combination of the scenarios. A trench and a via are formed in the interlayer dielectric layer 160, where the trench and via (as emphasized by dashed box 174) are miss-aligned over the top electrode145 to form the miss-aligned contact trench 176. The via section 174 is offset from the center of the top electrode 145 to create the miss alignment scenario. FIG. 14 illustrates that the via 174 is miss-aligned to the right, but the via 174 can be miss-aligned in any direction, such that, the via 174 is not aligned over the center of the top electrode. Since the depth/height/dimension D3 is such that miss-aligned contact trench 176 will be over etched because the longer etch time that is needed to etch other regions. The over etching will laterally etch the second spacer 155 instead of etching further downwards into the first spacer 150. The over etch portion of the miss-aligned contact trench 176, as emphasized by dashed box 176OE, illustrates how lateral cavities are formed in the second spacer 155 during the over etching of the miss-aligned contact trench 176. The over etched portion 176OE does not extend downwards into the first spacer 150, but instead extends laterally into the second spacer 155. Since the miss-aligned contact trench 176 was not aligned properly over the center of the top electrode 145, this will lead to the uneven laterally etching of the second spacer 155 during the over etching. Over etched portion 176OE illustrates that the over etching is more prominent to one side (the right side as illustrated) than another lateral direction in the second spacer 155. Over etched portion 176OE illustrates how the over etching follows the material within the second spacer 155 instead of extending downwards into the first spacer 150. The second spacer 155 prevents the etching of the first spacer 150, thus preventing the formation of defects that can be associated with over etching, during the etching process to form contact trenches in the memory region, logic region, other regions.

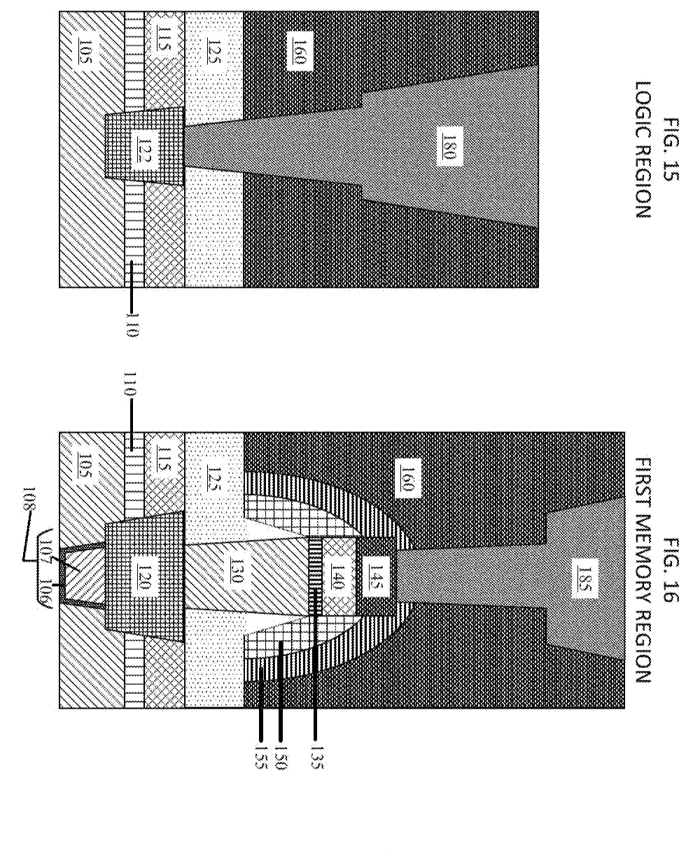

FIG. 15 illustrates the processing stage of the logic region after the formation of logic contact 180. A metallization process fills the logic contact via trench 165 with a conductive material to form the logic contact 180. The logic contact 180 can be comprised of, for example, Nb, NbN, W, WN, Ta, TaN, Ti, TiN, Ru, Cu, Co, W, Mo, WN, Cr, V, Pd, Pt, Rh, Sc, Al, other high melting point metals, other suitable conductive metals, conductive alloys, or a combination thereof.

FIG. 16 illustrates the processing stage of the first memory region after the formation of extended contact 185. A metallization process fills the extended trench 167 with a conductive material to form the extended contact 185. The extended contact 185 can be comprised of, for example, Nb, NbN, W, WN, Ta, TaN, Ti, TiN, Ru, Cu, Co, W, Mo, WN, Cr, V, Pd, Pt, Rh, Sc, Al, other high melting point metals, other suitable conductive metals, conductive alloys, or a combination thereof. A MRAM cell includes the extended contact 185, the top electrode 145, MTJ layer 140, the third layer 135, the bottom electrode 130, and the metal/line connector 120. The extended contact 185 is in contact with the top surface of the top electrode 145 and does not extend laterally since there was no lateral over etch of the second spacer 155.

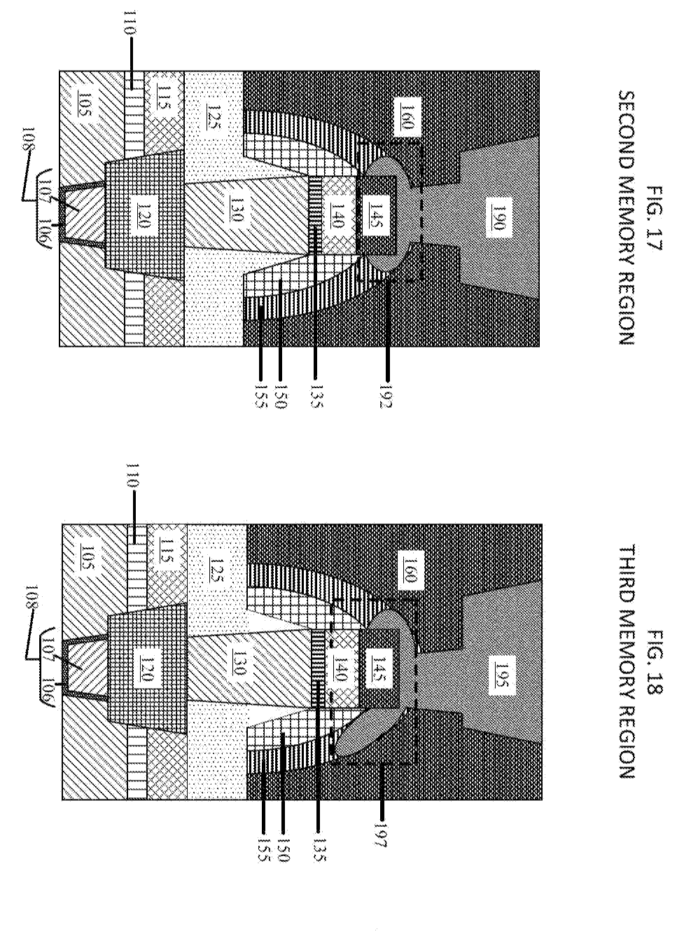

FIG. 17 illustrates the processing stage of the second memory region after the formation of the ideal aligned contact 190. A metallization process fills the ideal aligned contact trench 172 with a conductive material to form the ideal aligned contact 190. The ideal aligned contact 190 can be comprised of, for example, Nb, NbN, W, WN, Ta, TaN, Ti, TiN, Ru, Cu, Co, W, Mo, WN, Cr, V, Pd, Pt, Rh, Sc, Al, other high melting point metals, other suitable conductive metals, conductive alloys, or a combination thereof. A MRAM cell includes the ideal aligned contact 190, the top electrode 145, MTJ layer 140, the third layer 135, the bottom electrode 130, and the metal/line connector 120. The ideal aligned contact 190 includes lateral protrusions (as emphasized by dashed box 192) that are located in the second spacer 155. The lateral protrusions of the ideal aligned contact 190 are in contact with the sidewalls of the top electrode 145 and the second spacer 155. The lateral protrusions of the ideal aligned contact 190 can be in contact with a top surface of the first spacer 150, but the lateral protrusions of the ideal aligned contact 190 do not extend into the first spacer 150. The lateral protrusions of the ideal aligned contact 190 will have substantially have the same shape because of the ideal alignment of the via section 170 of the ideal aligned contact trench 172. The lateral protrusions ideal aligned contact 190 wrap around the sides of the top electrode 145. Therefore, the contact surface area between the ideal aligned contact 190 and the top electrode 145 is increased by controlling the over etching to extend laterally into the second spacer 155.

A magnetoresistive-random-access-memory (MRAM) cell includes a bottom electrode 130, a first layer 135 is located on top of the bottom electrode 130, a magnetic-tunnel-junction (MTJ) 140 is located on top of the first layer 135 (wherein the MTJ 140 includes a reference layer, a tunnel barrier layer, and a free layer), a top electrode 145 is located on top of the MTJ 140. A first spacer 150 is located around the bottom electrode 130, the first layer 135, the MTJ 140, and a portion of the top electrode 145. A second spacer 155 is located around the first spacer 150. The second spacer 155 is located around the side surfaces and the top surface of the top electrode 145. A contact 190, 195 is connected to the top electrode 145, where the contact 190, 195 extends through the second spacer 155 to contact the top electrode 145.

The first spacer 150 is in direct contact with a side surface of the first layer 135, a side surface of the MTJ 140, and a side surface of the top electrode 145.

The second spacer 155 is located around the first spacer 150, such that the second spacer 155 extends downwards along the sides of the first spacer 150. A base of the first spacer 150 and a base of the second spacer 155 are substantially on the same level (see, for example, FIGS. 17 and 18 where the base of the first spacer 150 and the second spacer 155 are located on top of the second layer 125).

The contact 190, 195 wraps around the sides of the top electrode 145. The contact 190, 195 includes protrusions (as emphasized by dashed boxes 192, 197) that are located on the sides of the top electrode 145. The protrusions (as emphasized by dashed boxes 192, 197) of the contact 190, 195 extend laterally into the second spacer 155. The protrusions (as emphasized by dashed box 192) of the contact 190 have substantially the same dimensions on different sides of the top electrode 145. The contact 190 does not extend into the first spacer 150.

FIG. 18 illustrates the processing stage of the second memory region after the formation of the miss-aligned contact 195. A metallization process fills the miss-aligned contact trench 176 with a conductive material to form the miss-aligned contact 195. The miss-aligned contact 195 can be comprised of, for example, Nb, NbN, W, WN, Ta, TaN, Ti, TiN, Ru, Cu, Co, W, Mo, WN, Cr, V, Pd, Pt, Rh, Sc, Al, other high melting point metals, other suitable conductive metals, conductive alloys, or a combination thereof. A MRAM cell includes the miss-aligned contact 195, the top electrode 145, MTJ layer 140, the third layer 135, the bottom electrode 130, and the metal/line connector 120. The miss-aligned contact 195 includes lateral protrusions (as emphasized by dashed box 197) that are located in the second spacer 155. The lateral protrusions of the miss-aligned contact 195 are in contact with the sidewalls of the top electrode 145 and the second spacer 155. The lateral protrusions of the miss-aligned contact 195 can be in contact with a top surface of the first spacer 150, but the lateral protrusions of the miss-aligned contact 195 do not extend into the first spacer 150. The lateral protrusions of the miss-aligned contact 195 will have different shapes/profiles because of the miss-alignment of the via section 174 of the miss-aligned contact trench 176. One of the protrusions of the miss-aligned contact 195 can extend farther into the second spacer 155 the other protrusions (as FIG. 18 illustrates that the right protrusion extends farther and downwards along the second spacer 155 than the protrusion on the left side of the top electrode 145). The lateral protrusions ideal miss-aligned contact 195 wrap around the sides of the top electrode 145. Therefore, the contact surface area between the miss-aligned contact 195 and the top electrode 145 is increased by controlling the over etching to extend laterally into the second spacer 155.

A magnetoresistive-random-access-memory (MRAM) cell includes a bottom electrode 130, a first layer 135 is located on top of the bottom electrode 130, a magnetic-tunnel-junction (MTJ) 140 is located on top of the first layer 135 (wherein the MTJ 140 includes a reference layer, a tunnel barrier layer, and a free layer), a top electrode 145 is located on top of the MTJ 140. A first spacer 150 is located around the bottom electrode 130, the first layer 135, the MTJ 140, and a portion of the top electrode 145. A second spacer 155 is located around the first spacer 150. The second spacer 155 is located around the side surfaces and the top surface of the top electrode 145. A contact 195 is connected to the top electrode 145, where the contact 195 extends through the second spacer 155 to contact the top electrode 145. The contact 195 wraps unevenly around the sides of the top electrode 145 (see, for example FIG. 18).

The first spacer 150 is in direct contact with a side surface of the first layer 135, a side surface of the MTJ 140, and a side surface of the top electrode 145.

The second spacer 155 is located around the first spacer 150, such that the second spacer 155 extends downwards along the sides of the first spacer 150. A base of the first spacer 150 and a base of the second spacer 155 are substantially on the same level (see, for example, FIGS. 17 and 18 where the base of the first spacer 150 and the second spacer 155 are located on top of the second layer 125). The spacer etch back process on the second spacer 155 may gouge into the second layer 125 so the second spacer 155 could be slightly deeper base when compared to the base of the first spacer 150.

The contact 195 includes protrusions (as emphasized by dashed box 197) that are located on the sides of the top electrode 145. The protrusions (as emphasized by dashed box 197) of the contact 195 extend laterally into the second spacer 155. One protrusion (as emphasized by dashed box 197) of the contact 195 is located on a first side of the top electrode 145 has a first lateral dimension and a one protrusion (as emphasized by dashed box 197) located on a second side of the top electrode 145 has a second lateral dimeson. The first lateral dimension of the one protrusion (as emphasized by dashed box 197) of the contact 195 located on a first side of the top electrode 145 is different than the second lateral dimension of the one protrusion (as emphasized by dashed box 197) located on a second side of the top electrode 145 (see, for example, FIG. 18, where the protrusions (as emphasized by dashed box 197) that are located on different sides of the top electrode 145 have different lateral dimensions). The one protrusion (as emphasized by dashed box 197) of the contact 195 having the second lateral dimension extends along the second spacer 155 to extend below a bottom surface of the top electrode 145 (see, for example, FIG. 18, where the protrusions (as emphasized by dashed box 197) extends along the second spacer 155 to a depth that is lower than the bottom surface of the top electrode 145). The contact 195 does not extend into the first spacer 150.

A microelectronic structure that includes a magnetoresistive-random-access-memory (MRAM) array that includes a plurality of MRAM cells. Each of the plurality of MRAM cells includes a bottom electrode 130, a first layer 135 is located on top of the bottom electrode 130, a magnetic-tunnel-junction (MTJ) 140 is located on top of the first layer 135 (wherein the MTJ 140 includes a reference layer, a tunnel barrier layer, and a free layer), a top electrode 145 is located on top of the MTJ 140. A first spacer 150 is located around the bottom electrode 130, the first layer 135, the MTJ 140, and a portion of the top electrode 145. A second spacer 155 is located around the first spacer 150. The second spacer 155 is located around the side surfaces and the top surface of the top electrode 145. A plurality of contacts 190, 195 where each of the plurality of contacts 190, 195 is connected to one of the MRAM cells. Each of the plurality of contacts 190, 195 is connected to the top electrode 145 of one of the plurality of MRAM cells. The contact 195 wraps unevenly around the sides of the top electrode 145 or the contact 190 wraps evenly around the sides of the top electrode 145 (see, for example, FIGS. 17 and 18, as emphasized by dashed boxes 192, 197).

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A magnetoresistive-random-access-memory (MRAM) cell structure comprising:
a bottom electrode;
a first layer is located on top of the bottom electrode;
a magnetic-tunnel-junction (MTJ) is located on top of the first layer;
a top electrode is located on top of the MTJ;
a first spacer is located around the bottom electrode, the first layer, the MTJ, and a portion of the top electrode;
a second spacer is located around the first spacer, wherein the second spacer is located around side surfaces and a top surface of the top electrode; and
a contact is connected to the top electrode, wherein the contact extends through the second spacer to contact the top electrode.

2. The MRAM cell structure of claim 1, wherein the first spacer is in direct contact with a side surface of the first layer, a side surface of the MTJ, and a side surface of the top electrode.

3. The MRAM cell structure of claim 2, wherein the second spacer is located around the first spacer, such that the second spacer extends downwards along sides of the first spacer.

4. The MRAM cell structure of claim 3, wherein a base of the first spacer and a base of the second spacer are substantially on a same level.

5. The MRAM cell structure of claim 4, wherein the contact wraps around the sides of the top electrode.

6. The MRAM cell structure of claim 5, wherein the contact includes protrusions that are located on the sides of the top electrode.

7. The MRAM cell structure of claim 6, wherein the protrusions of the contact extend laterally into the second spacer.

8. The MRAM cell structure of claim 7, wherein the protrusions of the contact have substantially same dimensions on different sides of the top electrode.

9. The MRAM cell structure of claim 8, wherein the contact does not extend into the first spacer.

10. A magnetoresistive-random-access-memory (MRAM) cell structure comprising:
a bottom electrode;
a first layer located on top of the bottom electrode;
a magnetic-tunnel-junction (MTJ) located on top of the first layer;
a top electrode located on top of the MTJ;
a first spacer located around the bottom electrode, the first layer, the MTJ, and portion of the top electrode;
a second spacer located around the first spacer, wherein the second spacer is located around side surfaces and a top surface of the top electrode; and
a contact connected to the top electrode, wherein the contact extends through the second spacer to contact the top electrode, wherein the contact wraps unevenly around sides of the top electrode.

11. The MRAM cell structure of claim 10, wherein the first spacer is in direct contact with a side surface of the first layer, a side surface of the MTJ, and a side surface of the top electrode.

12. The MRAM cell structure of claim 11, wherein the second spacer is located around the first spacer, such that the second spacer extends downwards along sides of the first spacer.

13. The MRAM cell structure of claim 12, wherein a base of the first spacer and a base of the second spacer are substantially on a same level.

14. The MRAM cell structure of claim 10, wherein the contact includes protrusions that are located on the sides of the top electrode.

15. The MRAM cell structure of claim 14, wherein the protrusions of the contact extend laterally into the second spacer.

16. The MRAM cell structure of claim 7, wherein one protrusion of the contact is located on a first side of the top electrode has a first lateral dimension and a one protrusion is located on a second side of the top electrode has a second lateral dimeson.

17. The MRAM cell structure of claim 16, wherein the first lateral dimension of the one protrusion of the contact located on a first side of the top electrode is different than the second lateral dimension of the one protrusion located on a second side of the top electrode.

18. The MRAM cell structure of claim 17, wherein the one protrusion of the contact having the second lateral dimension extends along the second spacer to extend below a bottom surface of the top electrode.

19. The MRAM cell structure of claim 18, wherein the contact does not extend into the first spacer.

20. A microelectronic structure comprising:
a magnetoresistive-random-access-memory (MRAM) array that includes a plurality of MRAM cells, wherein each of the plurality of MRAM cells includes:
a bottom electrode;
a first layer located on top of the bottom electrode;
a magnetic-tunnel-junction (MTJ) located on top of the first layer;
a top electrode located on top of the MTJ;
a first spacer located around the bottom electrode, the first layer, the MTJ, and portion of the top electrode;
a second spacer located around the first spacer, wherein the second spacer is located around side surfaces and a top surface of the top electrode;
a plurality of contacts, wherein each of the plurality of contacts is connected to one of the MRAM cells, wherein each of the plurality of contacts is connected to the top electrode of one of the plurality of MRAM cells, wherein the contact wraps unevenly around the sides of the top electrode or the contact wraps evenly around the sides of the top electrode.
